(19) United States
(12) Patent Application Publication
(10) Pub. No.: US 2025/0386585 A1
(43) Pub. Date: Dec. 18, 2025

(54) INTEGRATED CIRCUIT DEVICE INCLUDING MULTI-LAYER CHANNEL LINE

(71) Applicant: SAMSUNG ELECTRONICS CO., LTD., SUWON-SI, GYEONGGI-DO (KR)

(72) Inventors: Donghoon Hwang, Suwon-si (KR); Byungho Moon, Suwon-si (KR); Jaeho Jeon, Suwon-si (KR); Wonchang Lee, Suwon-si (KR)

(21) Appl. No.: 18/984,624

(22) Filed: Dec. 17, 2024

(30) Foreign Application Priority Data
Jun. 17, 2024 (KR) 10-2024-0078473

(51) Int. Cl. H10D 84/01; H10D 30/01; H10D 30/67; H10D 84/83

(52) U.S. Cl. CPC H10D 84/0128; H10D 30/014; H10D 30/0191; H10D 30/0195; H10D 30/6735; H10D 84/0149; H10D 84/0151; H10D 84/832

(57) ABSTRACT

A method of manufacturing an integrated circuit device includes sequentially forming a lower channel stack, an intermediate layer, and an upper channel stack on a substrate, forming a recess space by removing portions of the lower and upper channel stacks, and the intermediate layer, forming, sequentially, an insulating layer, a lower source/drain region and an upper source/drain region in the recess space, removing a sacrificial layer included in the lower and upper channel stacks and the intermediate layer, and forming a lower gate insulating layer on the lower channel stack and an upper gate insulating layer on the upper channel stack, forming a lower gate line on the lower gate insulating layer and an upper gate line on the upper gate insulating layer, and forming a gate isolation structure after the forming of the lower gate line and before the forming of the upper gate line.

### CROSS-REFERENCE TO RELATED APPLICATION

This application is based on and claims priority under 35 U.S.C. § 119 to Korean Patent Application No. 10-2024-0078473, filed on Jun. 17, 2024, in the Korean Intellectual Property Office, the disclosure of which is incorporated by reference herein in its entirety.

### BACKGROUND

### 1. Technical Field

The inventive concept relates to a method of manufacturing an integrated circuit device. More particularly, the inventive concept relates to a method of manufacturing an integrated circuit device including a multi-layer channel line.

### 2. Discussion of Related Art

Integrated circuit devices may be scaled-down to increase efficiency and operation speed. As the integrated circuit devices are scaled down, it may be necessary to secure the operation speed and an operation accuracy thereof.

A wiring structure of the integrated circuit devices may include conductive lines and an insulating structure. The conductive lines need a stable configuration and efficient arrangement in a relatively small area, and the insulating structure needs to be configured to prevent a short-circuit effect between conductive regions.

### SUMMARY

The inventive concept provides an integrated circuit device having improved operating characteristics and increased reliability.

The inventive concept provides an integrated circuit device having improved structural stability.

Also, aspects of the technical idea of the present inventive concept are not limited to those mentioned above, and the inventive concept can be clearly understood by those skilled in the art from the description herein.

According to an aspect of the inventive concept, there is provided a method of manufacturing an integrated circuit device.

The method includes forming a placeholder in an upper portion of a substrate, forming a lower channel stack extending in a first horizontal direction, by alternately vapor-depositing a plurality of lower nanosheets and a plurality of lower sacrificial layers on the substrate, and forming an upper channel stack extending in the first horizontal direction, by alternately vapor-depositing a plurality of upper nanosheets and a plurality of upper sacrificial layers above the lower channel stack, forming a recess space by removing portions of the upper channel stack, the lower channel stack, and the placeholder and forming an inner spacer in an upper portion of the placeholder, forming, sequentially, an insulating layer, a lower source/drain region and an upper source/drain region in the recess space, removing the plurality of lower sacrificial layers and the plurality of upper sacrificial layers, forming a lower gate insulating layer covering exposed surfaces of the lower source/drain region and the plurality of lower nanosheets, and forming an upper gate insulating layer covering exposed surfaces of the upper source/drain region and the plurality of upper nanosheets, forming a lower gate line on the lower gate insulating layer and forming an upper gate line on the upper gate insulating layer, forming an upper contact, a gate contact and an upper via, on the upper channel stack and the upper source/drain region, exposing the placeholder by polishing the substrate, removing the placeholder from the substrate and forming a lower contact in a space from which the placeholder has been removed, removing the substrate and filling a space from which the substrate has been removed with a first base insulating layer, forming a second based insulating layer on the first base insulating layer and the lower contact; and forming a lower via penetrating the first base insulating layer and contacting the lower contact, and forming a lower gate contact penetrating the first base insulating layer and contacting the lower channel stack.

According to another aspect of the inventive concept, there is provided a method of manufacturing an integrated circuit device. The method includes forming a placeholder in an upper portion of a substrate, the placeholder being spaced apart from an adjacent placeholder in a first horizontal direction and extending in a second horizontal direction, forming, sequentially, a lower channel stack, an intermediate layer and an upper channel stack, on the substrate, forming a recess space by removing portions of the upper channel stack, the intermediate layer, the lower channel stack, and the placeholder, removing an upper portion of the placeholder and forming an inner spacer in the upper portion of the placeholder, forming, sequentially, an insulating layer, a lower source/drain region and an upper source/drain region in the recess space, removing a sacrificial layer included in the lower channel stack and the upper channel stack and the intermediate layer and forming a lower gate insulating layer on an exposed surface of the lower channel stack and an upper gate insulating layer on an exposed surface of the upper channel stack, forming a lower gate line on the lower gate insulating layer and an upper gate line on the upper gate insulating layer, forming an upper contact, a gate contact and an upper via, on the upper channel stack and the upper source/drain region, exposing the placeholder by polishing the substrate, removing the placeholder from the substrate and forming a lower contact in a space from which the placeholder has been removed, removing the substrate and filling a space from which the substrate has been removed with a first base insulating layer, forming a second based insulating layer on the first base insulating layer and the lower contact; forming a lower contact via penetrating the first base insulating layer and contacting the lower contact and forming a lower gate contact penetrating the first base insulating layer and contacting the lower channel stack, and forming a gate isolation structure between the lower gate line and the upper gate line after the forming of the lower gate line and before the forming of the upper gate line.

According to a further aspect of the inventive concept, there is provided a method of manufacturing an integrated circuit device. The method includes providing a substrate including a placeholder disposed in an upper portion thereof, forming, sequentially, a lower channel stack, an intermediate layer and an upper channel stack, on the substrate, forming a recess space by removing portions of the upper channel stack, the intermediate layer, the lower channel stack, and the placeholder, to expose the substrate, etching an upper portion of the placeholder and forming an inner spacer on an upper portion of the placeholder, forming, sequentially, an insulating layer, a lower source/drain region of a first conductivity type and an upper source/drain region of a second conductivity type in the recess space, removing a sacrificial layer included in the lower channel stack and the upper channel stack and the intermediate layer, forming a lower gate insulating layer on an exposed surface of the lower channel stack, forming an upper gate insulating layer on an exposed surface of the upper channel stack, forming an insulating structure in a space from which the intermediate layer has been removed, and forming a gate forming conductive layer, forming a lower gate line by removing an upper portion of the gate forming conductive layer, forming a gate isolation structure on the lower gate line, wherein a top surface of the gate isolation structure is at a lower vertical level than a top surface of the insulating structure, forming an upper gate line on the gate isolation structure, forming an upper contact, a gate contact and an upper via, on the upper channel stack and the upper source/drain region, and forming a front wiring structure on the upper contact, the gate contact, and the upper via, exposing the placeholder by polishing the substrate, removing the placeholder from the substrate and forming a lower contact in a space from which the placeholder has been removed, removing the substrate and filling a space from which the substrate has been removed with a first base insulating layer, and forming a lower contact via penetrating the first base insulating layer and contacting the lower contact and a lower gate contact penetrating the first base insulating layer and contacting the lower channel stack.

### BRIEF DESCRIPTION OF THE DRAWINGS

Embodiments will be more clearly understood from the following detailed description taken in conjunction with the accompanying drawings in which:

FIG. 1 is a schematic layout diagram illustrating an integrated circuit device according to embodiments;

FIG. 2 is a cross-sectional view of the integrated circuit device of FIG. 1, taken along line A-A′ in FIG. 1;

FIG. 3A, FIG. 3B, and FIGS. 4 to 24 are cross-sectional views and perspective views illustrating sequential processes in a method of manufacturing an integrated circuit device, according to embodiments;

FIG. 25A, FIG. 25B, and FIG. 25C are schematic cross-sectional views illustrating part of a method of manufacturing an integrated circuit device, according to embodiments; and

FIG. 26A and FIG. 26B are schematic cross-sectional views illustrating part of an integrated circuit device, according to some embodiments.

### DETAILED DESCRIPTION

Hereinafter, embodiments will be described with reference to the accompanying drawings. In the drawing, like reference characters denote like elements, and redundant descriptions thereof will be omitted.

The following detailed description is provided to assist the reader in gaining a comprehensive understanding of methods, apparatuses, and/or systems described herein. As embodiments allow for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed in embodiments. For example, the sequences of operations described herein are examples, and are not limited to those set forth herein, but may be changed as will be apparent after an understanding of the disclosure of this application, with the exception of operations necessarily occurring in a certain order. In the description of embodiments, certain detailed descriptions of the related art may be omitted for increased clarity or conciseness.

In the drawings, an X axis direction and a Y axis direction indicate directions parallel to a front or top surface and/or a back or bottom surface of a layer, and the X axis direction and the Y axis direction may be directions perpendicular to each other. A Z axis direction may indicate a direction perpendicular to the top surface or the bottom surface of the integrated circuit device 100. In other words, the Z axis direction may be a direction perpendicular to an X-Y plane. Also, in the drawings, a first horizontal direction, a second horizontal direction, and a vertical direction may be understood as follows; the first horizontal direction may be understood as the X axis direction, the second horizontal direction may be understood as the Y axis direction, and the vertical direction may be understood as the Z axis direction.

Directional phrases and terms may be used for understanding of the disclosure. For example, a top surface may be an upper surface in an illustration. However, this is not intended to limit embodiments. For example, the layer may be turned over, and a top surface thereof may become a bottom surface.

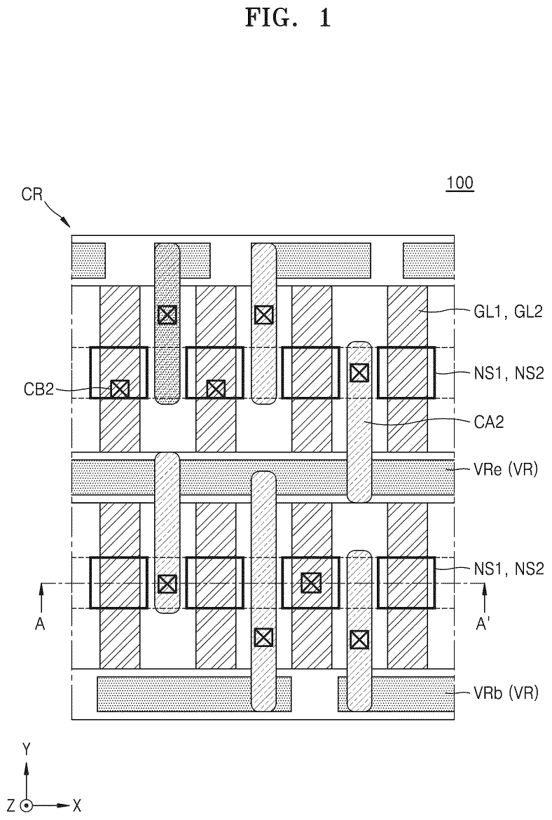

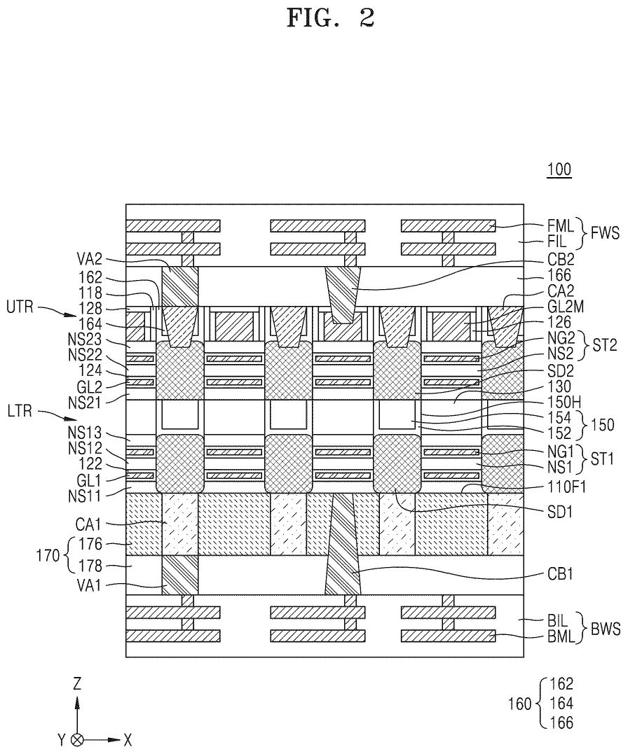

FIG. 1 is a schematic layout diagram illustrating an integrated circuit device 100 according to embodiments. FIG. 2 is a cross-sectional view of the integrated circuit device 100 of FIG. 1, taken along line A-A′.

Referring to FIG. 1 and FIG. 2, the integrated circuit device 100 may include a plurality of cells CR. Each of the cells CR may include a plurality of lower transistors LTR and a plurality of upper transistors UTR at a different vertical level than the lower transistors LTR in a vertical direction (a Z axis direction). For example, the upper transistors UTR may be at a higher vertical level than the lower transistors LTR. In this case, each of the cells CR may be include a multi-layer channel line structure, for example, a vertically stacked field effect transistor (FET) structure. In the integrated circuit device 100, a plurality of the multi-layer channel line structures may be spaced apart from each other in the first horizontal direction and/or the second horizontal direction.

Each of the cells CR may include a region in which various kinds of logic cells included in a logic circuit may be arranged.

The integrated circuit device 100 may further include a front wiring structure FWS disposed at a higher vertical level than the upper transistors UTR and a back wiring structure BWS disposed at a lower vertical level than the lower transistors LTR. In embodiments, the front wiring structure FWS may be configured to apply a signal voltage. The front wiring structure FWS may be configured to apply the signal voltage to the lower transistors LTR and the upper transistors UTR. In embodiments, the back wiring structure BWS may be configured to apply a power supply voltage and a ground voltage. The back wiring structure BWS may be configured to apply the power supply voltage and the ground voltage to the lower transistors LTR and the upper transistors UTR.

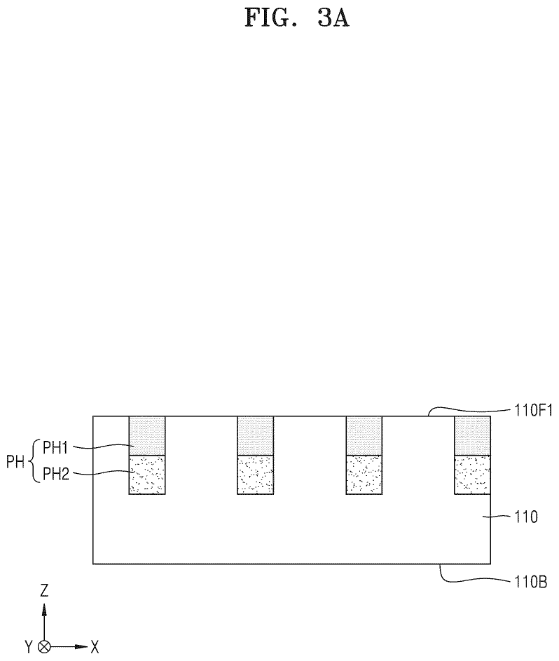

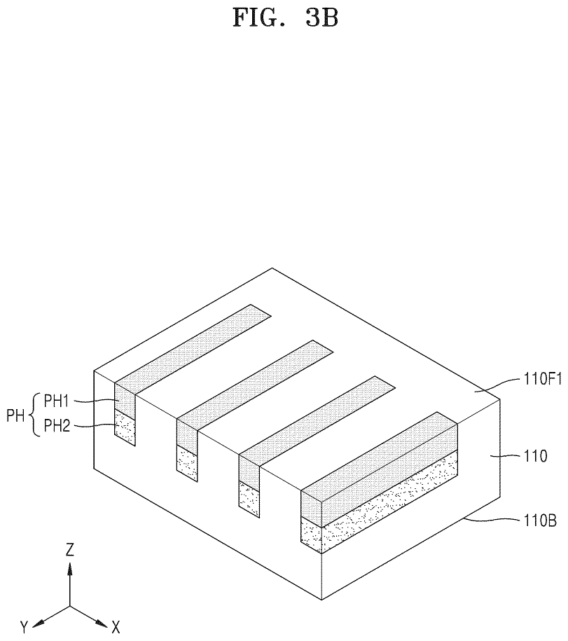

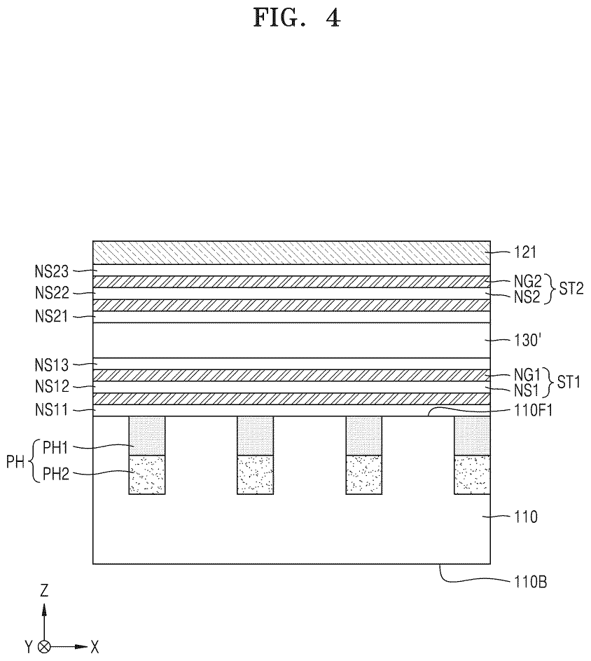

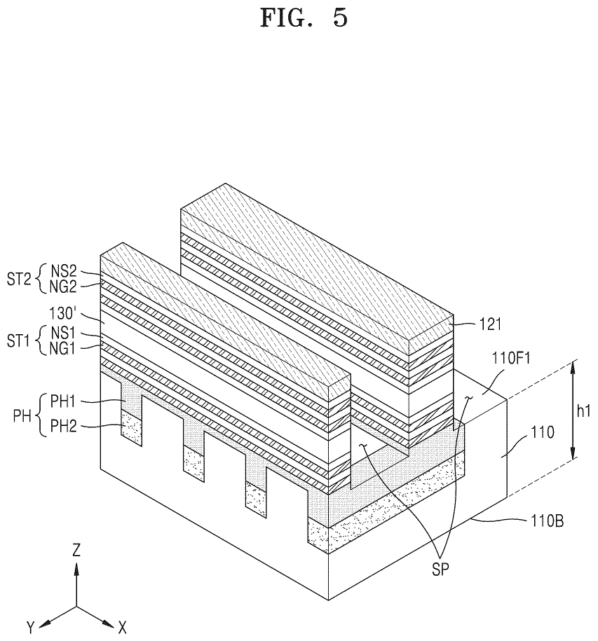

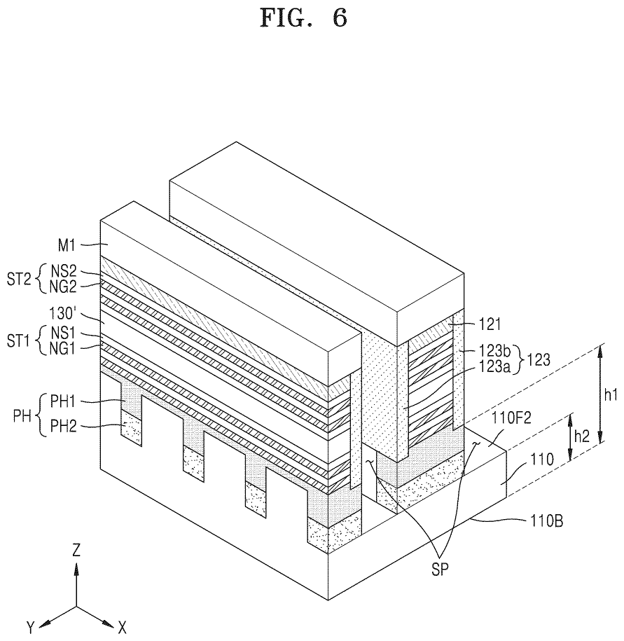

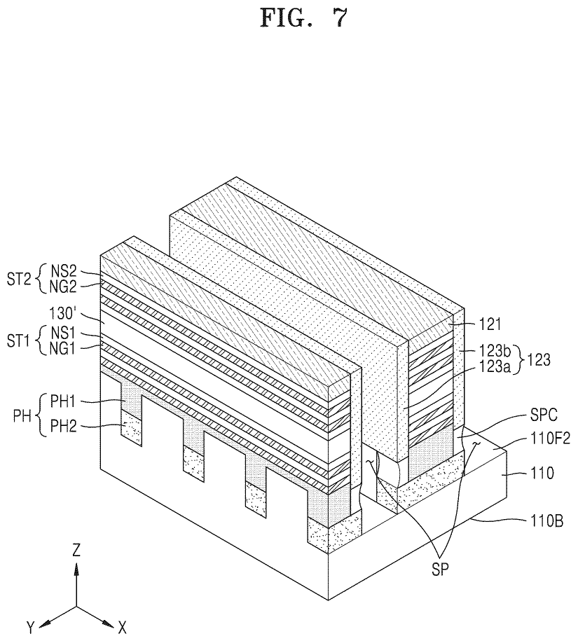

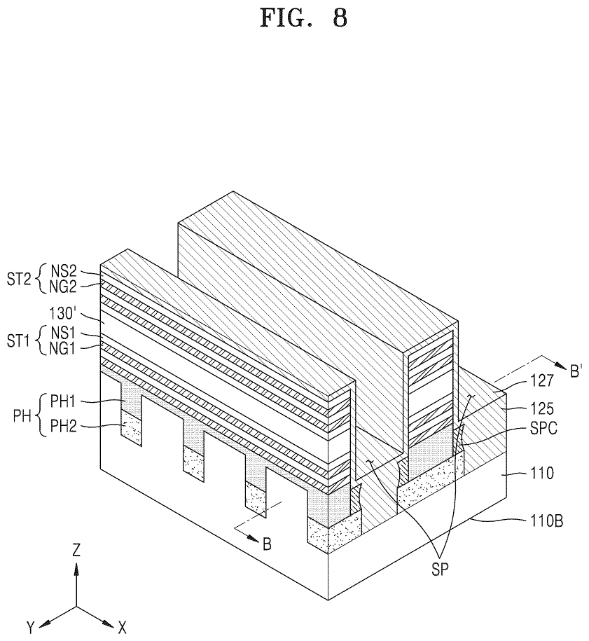

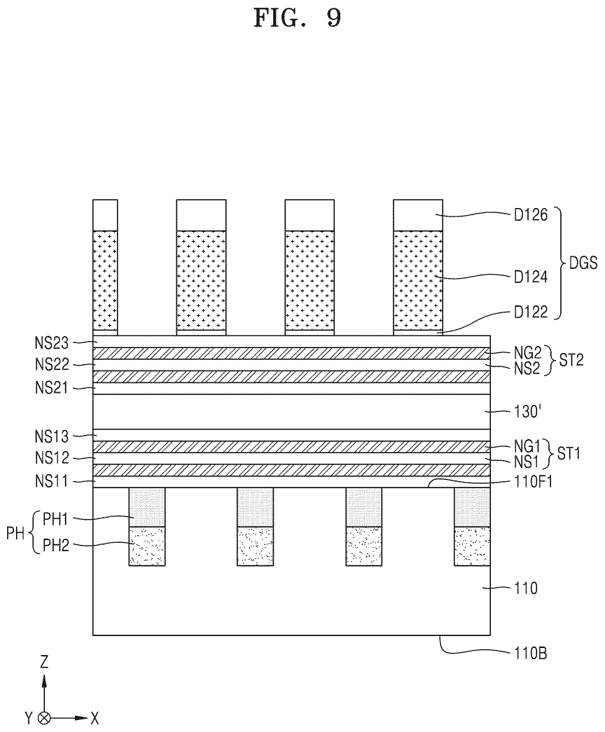

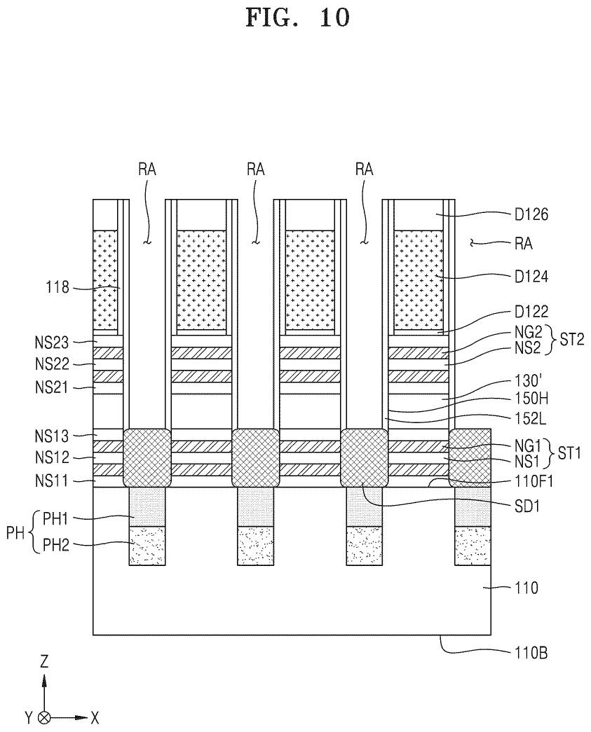

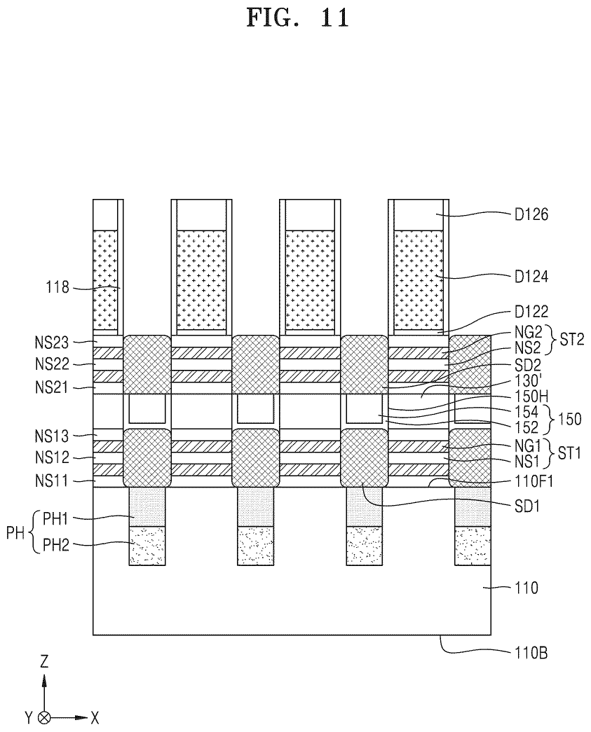

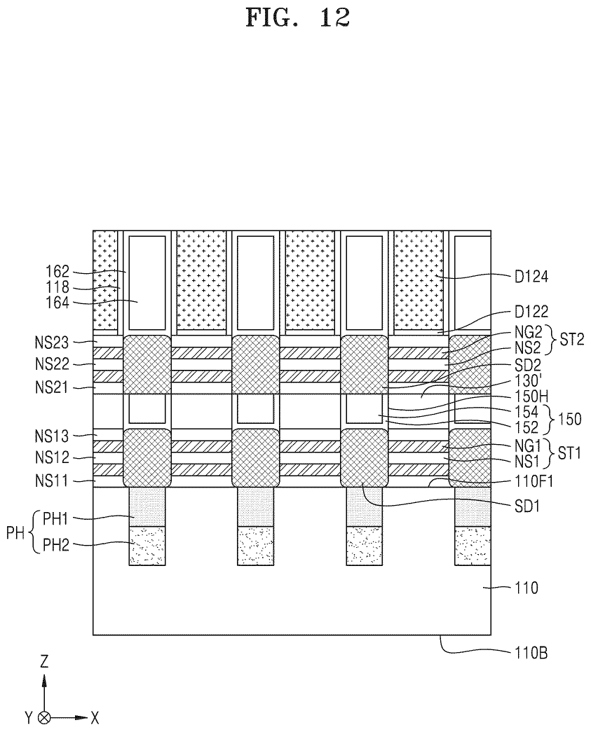

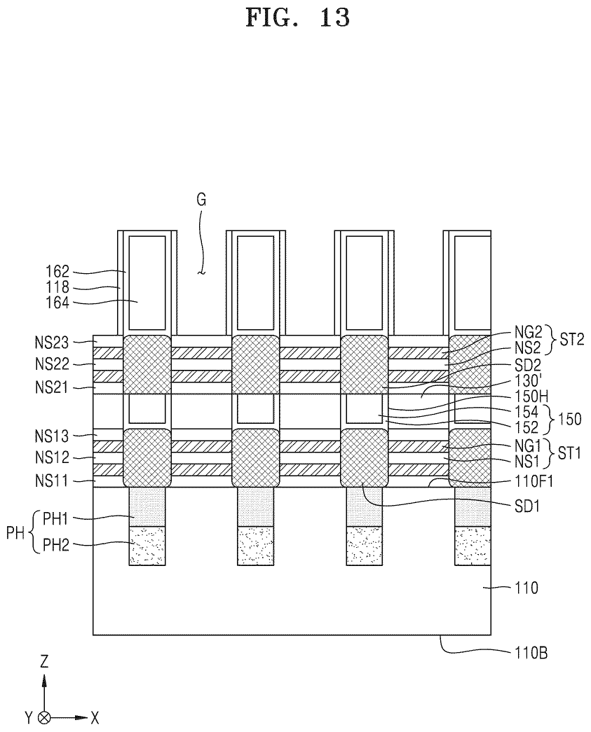

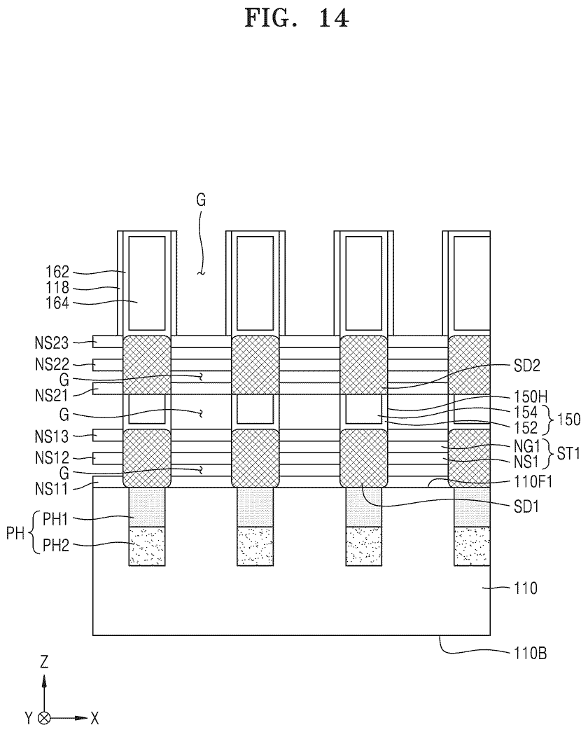

FIG. 1, FIG. 2, FIG. 3A, FIG. 3B, and FIGS. 4 to 24 illustrate embodiments in which the integrated circuit device 100 may form a logic cell including a gate all around field-effect transistor (GAAFET) device, such as a device using multiple sheets as channels in a FET. However, the inventive concept is not limited thereto. The integrated circuit device 100 may include a planar FET device, a fin FET device, or a two-dimensional (2D) material-based FET device like a MoS₂ semiconductor gate electrode.

Each of the lower transistors LTR may include a plurality of lower nanosheets NS1, which may be spaced apart from each other in the vertical direction (the Z axis direction), a lower source/drain region SD1 connected to the lower nanosheets NS1, a lower gate line GL1 surrounding at least a portion of the lower nanosheets NS1, and a lower contact CA1 disposed on the bottom surface of the lower source/drain region SD1.

Each of the upper transistors UTR may include a plurality of upper nanosheets NS2, which may be spaced apart from each other in the vertical direction (the Z axis direction), an upper source/drain region SD2 connected to the upper nanosheets NS2, an upper gate line GL2 surrounding at least a portion of the upper nanosheets NS2, and an upper contact CA2 disposed on the top surface of upper source/drain region SD2.

In embodiments, the lower transistors LTR and the upper transistors UTR may include different types of transistors or the same types of transistor. In embodiments, the lower transistors LTR may include a P-channel metal-oxide semiconductor (PMOS) transistor and the upper transistors UTR may include an N-channel MOS (NMOS) transistor. In some embodiments, the lower transistors LTR may include an NMOS transistor and the upper transistors UTR may include a PMOS transistor. In some embodiments, the lower transistors LTR may include an NMOS transistor having a first threshold voltage and the upper transistors UTR may include an NMOS transistor having a second threshold voltage that is different from the first threshold voltage. In some embodiments, the lower transistors LTR may include a PMOS transistor having the first threshold voltage and the upper transistors UTR may include a PMOS transistor having the second threshold voltage that is different from the first threshold voltage.

Each of the lower nanosheets NS1 and the upper nanosheets NS2 may include a Group IV semiconductor such as Si or Ge, a Group IV-IV compound semiconductor such as SiGe or SiC, or a Group III-V compound semiconductor such as GaAs, InAs, or InP. The lower nanosheets NS1 may include first lower nanosheets NS11, second lower nanosheets NS12, and third lower nanosheets NS13, which may be spaced apart from one another in the vertical direction (the Z axis direction). The upper nanosheets NS2 may include first upper nanosheets NS21, second upper nanosheets NS22, and third upper nanosheets NS23, which may be spaced apart from one another in the vertical direction (the Z axis direction).

The lower source/drain region SD1 may be connected to end portions of the lower nanosheets NS1. The lower source/drain region SD1 may have a top surface, which may be at a higher level than a highest lower nanosheet NS1 (e.g., the third lower nanosheet NS13), and a bottom surface, which may be at a lower level than a lowest lower nanosheet NS1 (e.g., the first lower nanosheet NS11). In embodiments, the lower source/drain region SD1 may include, but not limited to, a doped SiGe film, a doped Ge film, a doped SiC film, or a doped InGaAs film.

The lower gate line GL1 may extend in a second horizontal direction (the Y axis direction) to surround at least a portion of the lower nanosheets NS1. A plurality of lower gate lines GL1 may be arranged apart from each other by a first gate distance in a first horizontal direction (the X axis direction). A lower gate insulating layer 122 may be disposed between each of the lower nanosheets NS1 and the lower gate line GL1, and between the lower source/drain region SD1 and the lower gate line GL1. The bottom surface and sidewall of the third lower nanosheet NS13 may be surrounded by the lower gate insulating layer 122 and the lower gate line GL1. The top surface of the third lower nanosheet NS13 may not be surrounded by the lower gate insulating layer 122 or the lower gate line GL1. The top surface and sidewall of the first lower nanosheet NS11 may be surrounded by the lower gate insulating layer 122 and the lower gate line GL1. The bottom surface of the first lower nanosheet NS11 may not be surrounded by the lower gate insulating layer 122 or the lower gate line GL1.

The upper source/drain region SD2 may be connected to end portions of the upper nanosheets NS2. The upper source/drain region SD2 may vertically overlap the lower source/drain region SD1 and may be apart from the lower source/drain region SD1 in the vertical direction (the Z axis direction). The upper source/drain region SD2 may have a top surface, which may be at a higher level than a highest upper nanosheet NS2 (e.g., the third upper nanosheet NS23), and a bottom surface, which may be at a lower level than a lowest upper nanosheet NS2 (e.g., the first upper nanosheet NS21). In embodiments, the upper source/drain region SD2 may include, but not limited to, a doped SiGe film, a doped Ge film, a doped SiC film, or a doped InGaAs film.

The upper gate line GL2 may extend in the second horizontal direction (the Y axis direction) to surround at least a portion of the upper nanosheets NS2. A plurality of upper gate lines GL2 may be arranged apart from each other by the first gate distance in the first horizontal direction (an X axis direction). The upper gate line GL2 may vertically overlap the lower gate line GL1. An upper gate insulating layer 124 may be disposed between each of the upper nanosheets NS2 and the upper gate line GL2, and between the upper source/drain region SD2 and the upper gate line GL2.

As illustrated in FIG. 2, the upper gate line GL2 may include a main gate portion GL2M disposed on the top surface of the third upper nanosheet NS23. A spacer 126 may be on each of opposite sidewalls of the main gate portion GL2M. A gate capping layer 128 may be disposed on the top surface of the main gate portion GL2M. The top surface and sidewall of the first upper nanosheet NS21 may be surrounded by the upper gate insulating layer 124 and the upper gate line GL2. The bottom surface of the first upper nanosheet NS21 may not be surrounded by the upper gate insulating layer 124 or the upper gate line GL2. For example, the bottom surface of the first upper nanosheet NS21 may be exposed by the upper gate insulating layer 124 or the upper gate line GL2.

In embodiments, the lower gate line GL1 and the upper gate line GL2 may include doped polysilicon, metal, conductive metal nitride, conductive metal carbide, conductive metal silicide, or a combination thereof. For example, the lower gate line GL1 and the upper gate line GL2 may include, but not limited to, Al, Cu, Ti, Ta, W, Mo, TaN, NiSi, CoSi, TiN, WN, TiAl, TiAlN, TaCN, TaC, or TaSiN, or a combination thereof. In embodiments, the lower gate line GL1 and the upper gate line GL2 may include a work function metal layer (not shown) and a gap-fill metal film (not shown). The work function metal layer may include at least one metal selected from Ti, W, Ru, Nb, Mo, Hf, Ni, Co, Pt, Yb, Tb, Dy, Er, or Pd. The gap-fill metal film may include a W film or an Al film. In some embodiments, the lower gate line GL1 and the upper gate line GL2 may include a stack structure of TiAlC/TiN/W, TiN/TaN/TiAlC/TiN/W, or TiN/TaN/TiN/TiAlC/TiN/W but are not limited thereto.

In embodiments, the lower gate insulating layer 122 and the upper gate insulating layer 124 may include a silicon oxide film, a silicon oxynitride film, a high-k dielectric film having a higher dielectric constant than a silicon oxide film, or a combination thereof. The high-k dielectric film may include metal oxide or metal oxynitride. For example, a high-k dielectric film that may be used for the lower gate insulating layer 122 and the upper gate insulating layer 124 may include, but not limited to, HfO₂, HfSIO, HfSION, HfTaO, HfTIO, HfZrO, ZrO₂, or Al₂O₃, or a combination thereof.

In embodiments, the spacer 126 may include silicon oxide (SiOₓ), silicon nitride (SiNₓ), silicon oxynitride (SiOₓN_{y}), silicon carbonitride (SiCₓN_{y}), or silicon oxycarbonitride (SiOₓC_{y}N_{z}), or a combination thereof. In embodiments, the gate capping layer 128 may include silicon nitride or silicon oxynitride.

The lower contact CA1 may be disposed on the bottom surface of the lower source/drain region SD1 (e.g., below the lower source/drain region SD1, as shown in FIG. 2, or at a lower vertical level than the lower source/drain region SD1). The upper contact CA2 may be disposed on the top surface of the upper source/drain region SD2 (e.g., at a higher vertical level than the upper source/drain region SD2, as shown in FIG. 2). In embodiments, the lower contact CA1 and the upper contact CA2 may include at least one selected from tungsten (W), cobalt (Co), molybdenum (Mo), nickel (Ni), ruthenium (Ru), copper (Cu), aluminum (Al), titanium (Ti), titanium nitride (TiN), tantalum (Ta), tantalum nitride (TaN), titanium silicon nitride (TiSiN), titanium silicide (TiSi), or tungsten silicide (WSi).

An insulating structure 130 may be disposed between the lower transistor LTR and the upper transistor UTR. The bottom surface of the lowest upper nanosheet NS2 (e.g., the first upper nanosheet NS21) and the bottom surface of the upper source/drain region SD2 may be on the top surface of the insulating structure 130. The top surface of the highest lower nanosheet NS1 (e.g., the third lower nanosheet NS13) and the top surface of the lower source/drain region SD1 may be below (e.g., at a lower vertical level than) the bottom surface of the insulating structure 130.

Although not shown, in embodiments, the insulating structure 130 may include a plurality of base insulating layers, which may be spaced apart from each other in the vertical direction (the Z axis direction), and at least one intermediate layer between the base insulating layers.

A vertical conductive rail VR may extend in the first horizontal direction (the X axis direction) and the vertical direction (the Z axis direction) between lower transistors LTR adjacent to each other in the second horizontal direction (the Y axis direction), and between upper transistors UTR adjacent to each other in the second horizontal direction (the Y axis direction). The vertical conductive rail VR may be in a vertical via trench, which may extend in the first horizontal direction (the X axis direction) and the vertical direction (the Z axis direction).

In embodiments, as shown in FIG. 1, the vertical conductive rail VR may include a line-type conductive rail VRe and a bar-type conductive rail VRb. For example, the line-type conductive rail VRe may extend in the first horizontal direction (the X axis direction) with a length that is greater than the width of each cell CR in the first horizontal direction (the X axis direction). The bar-type conductive rail VRb may extend in the first horizontal direction (the X axis direction) with a length that is less than the width of each cell CR in the first horizontal direction (the X axis direction). For example, a plurality of bar-type conductive rails VRb may be arranged in a line and apart from each other in the first horizontal direction (the X axis direction). For example, two to ten bar-type conductive rails VRb may be apart from each other in the first horizontal direction (the X axis direction) in each cell CR.

A vertical insulating pillar (not shown) may be disposed between adjacent bar-type conductive rails VRb. For example, a vertical insulating pillar (not shown) may be disposed between two adjacent bar-type conductive rails VRb. The vertical insulating pillar may include an insulating material, such as silicon oxide, silicon nitride, or silicon oxynitride.

In embodiments, the vertical conductive rail VR may include a wiring structure. The vertical conductive rail VR may transmit a power supply and/or a signal. For example, the vertical conductive rail VR may transmit a signal voltage, a power supply voltage, and/or a ground voltage from the front wiring structure FWS and the back wiring structure BWS to the lower transistor LTR and the upper transistor UTR. In some embodiments, the line-type conductive rail VRe may be configured to transmit the power supply voltage, and/or the ground voltage from the back wiring structure BWS to the lower transistor LTR and the upper transistor UTR, and the bar-type conductive rail VRb may be configured to transmit the signal voltage from the front wiring structure FWS to the lower transistor LTR and the upper transistor UTR.

A back insulating structure 170 may be disposed on the bottom surface of the lower source/drain region SD1 and the bottom surface of the lower nanosheet NS1 (below the lower source/drain region SD1 and the lower nanosheet NS1, as shown in FIG. 2). The back insulating structure 170 may include a first base insulating layer 176 and a second base insulating layer 178. The first base insulating layer 176 may be disposed on the bottom surface of the lower source/drain region SD1 and the bottom surface of the lower nanosheet NS1. The second base insulating layer 178 may be disposed on the bottom surface of the first base insulating layer 176 (below the first base insulating layer 176, as shown in FIG. 2).

An insulating line structure 150 may be arranged in an opening 150H, which may extend in the second horizontal direction (the Y axis direction) and passes through the insulating structure 130 and the back insulating structure 170. The insulating line structure 150 may include an insulating liner 152 disposed on the inner wall of the opening 150H, an insulating buried layer 154 disposed on the insulating liner 152 to fill the opening 150H, and a capping liner (not shown) covering the top surface of the insulating buried layer 154. The insulating line structure 150 may extend in the second horizontal direction (the Y axis direction) and cover the lower source/drain region SD1 and the lower contact CA1. For example, the insulating liner 152 may cover the top and bottom surfaces of the lower source/drain region SD1, and the capping liner may be in contact with the bottom surface of the upper source/drain region SD2.

A lower via VA1 may be electrically connected to the lower contact CA1 through the second base insulating layer 178.

The back wiring structure BWS may be disposed on the bottom surface of the back insulating structure 170 (below the back insulating structure 170, as shown in FIG. 2). The back wiring structure BWS may include a first wiring line BML and a first cover insulating layer BIL. The first wiring line BML may include a plurality of conductive patterns at different vertical levels and a plurality of conductive vias connecting the conductive patterns. The first cover insulating layer BIL may include a plurality of insulating layers, which may surround at least a portion the conductive patterns and the conductive vias.

A top insulating structure 160 may be disposed on the top surface of the upper source/drain region SD2 and above the upper gate line GL2. The top insulating structure 160 may include an etch stop layer 162, a protective layer 164, and an upper insulating layer 166. The etch stop layer 162 may be conformally disposed on the top surface of the upper source/drain region SD2, the top surface of the gate capping layer 128, and the spacer 126. The protective layer 164 may be disposed on the etch stop layer 162 and may fill the space between adjacent upper gate lines GL2. The protective layer 164 may fill the space between two adjacent upper gate lines GL2. The upper insulating layer 166 may be disposed on the etch stop layer 162 and the protective layer 164.

An upper via VA2 may be electrically connected to the upper contact CA2 through the upper insulating layer 166. An upper gate contact CB2 may be connected to the top surface of the upper gate line GL2 through the top insulating structure 160.

The front wiring structure FWS may be disposed on the top surface of the top insulating structure 160. The front wiring structure FWS may include a second wiring line FML and a second cover insulating layer FIL. The second wiring line FML may include a plurality of conductive patterns at different vertical levels and a plurality of conductive vias connecting the conductive patterns. The second cover insulating layer FIL may include a plurality of insulating layers, which may surround at least a portion of the conductive patterns and the conductive vias.

According to embodiments, the integrated circuit device 100 may have a three-dimensional (3D) FET structure, in which the lower transistor LTR is separated from the upper transistor UTR in the vertical direction (the Z axis direction), and may include an inner spacer having an indented structure. In addition, the lower width of a gate line may be greater than the lower width of a nanosheet in the second horizontal direction (the Y axis direction). Accordingly, the reliability of the integrated circuit device 100 may be increased.

FIG. 3A, FIG. 3B, and FIGS. 4 to 24 are cross-sectional views and perspective views illustrating sequential processes in a method of manufacturing an integrated circuit device, according to embodiments. In detail, FIG. 3B and FIGS. 5 to 8 are perspective views, and FIG. 3A and FIG. 4 and FIGS. 9 to 24 are cross-sectional views taken along line A-A′ in FIG. 1.

Referring to FIG. 3A and FIG. 3B, a substrate 110 including a front surface 110F1 and a back surface 110B may be prepared, and a placeholder PH may be formed by forming a recess having a certain depth from the front surface 110F1 of the substrate 110. The placeholder PH may include a first placeholder PH1 and a second placeholder PH2. In some embodiments, the placeholder PH may be formed by filling the recess formed in the substrate 110 with the second placeholder PH2, newly forming a recess in an upper portion of the second placeholder PH2, and filling the recess with the first placeholder PH1.

In embodiments, the first placeholder PH1 and the second placeholder PH2 may include SiGe. In embodiments, SiGe in the first placeholder PH1 may have a different Ge concentration than SiGe in the second placeholder PH2. Because the first placeholder PH1 has a different Ge concentration than the second placeholder PH2, the placeholder PH may have an effective etch selectivity in a subsequent process (see FIG. 7).

For example, a concentration of Ge in SiGe in the first placeholder PH1 may be greater than a concentration of Ge in SiGe in the second placeholder PH2. In some embodiments, the difference in Ge concentration between the first placeholder PH1 and the second placeholder PH2 may be about 10% to about 15%. However, this an example, and the inventive concept is not limited thereto. In some embodiments, a concentration of Ge in SiGe in the second placeholder PH2 may be greater than a concentration of Ge in SiGe in the first placeholder PH1.

The top surface of the placeholder PH may be at the same level as the front surface 110F1 of the substrate 110 in the vertical direction (the Z axis direction). A plurality of placeholders PH may be spaced apart from each other at regular intervals in the first horizontal direction (the X axis direction) and may each have a bar shape extending in the second horizontal direction (the Y axis direction).

Referring to FIG. 4, a lower channel stack ST1 may be formed on the substrate 110. The lower channel stack ST1 may include a plurality of lower nanosheets NS1 and a plurality of lower sacrificial layers NG1 alternating with the lower nanosheets NS1. Although not shown in FIG. 4, a base insulating layer may be disposed between the front surface 110F1 of the substrate 110 and the lower channel stack ST1.

The lower nanosheets NS1 may include a Group IV semiconductor such as Si or Ge, a Group IV-IV compound semiconductor such as SiGe or SiC, or a Group III-V compound semiconductor such as GaAs, InAs, or InP. The lower sacrificial layers NG1 may include a material having an etch selectivity with respect to the lower nanosheets NS1. In some embodiments, the lower nanosheets NS1 may include silicon (Si) and the lower sacrificial layers NG1 may include silicon germanium (SiGe). In embodiments, the lower nanosheets NS1 and the lower sacrificial layers NG1 may be formed by an epitaxial growth process. The epitaxial growth process may include vapor-phase epitaxy (VPE), chemical vapor deposition (CVD) such as ultra-high vacuum (UHV)-CVD, molecular beam epitaxy, or a combination thereof.

An intermediate layer 130′ may be formed on the lower channel stack ST1. In embodiments, the intermediate layer 130′ may include SiGe.

An upper channel stack ST2 may be formed on the intermediate layer 130′. The upper channel stack ST2 may include a plurality of upper nanosheets NS2 and a plurality of upper sacrificial layers NG2 alternating with the upper nanosheets NS2.

The upper nanosheets NS2 may include a Group IV semiconductor such as Si or Ge, a Group IV-IV compound semiconductor such as SiGe or SiC, or a Group III-V compound semiconductor such as GaAs, InAs, or InP. The upper sacrificial layers NG2 may include a material having an etch selectivity with respect to the upper nanosheets NS2.

Referring to FIG. 5, an upper insulating layer 121 covering a portion of the upper channel stack ST2 may be formed. Each of the upper channel stack ST2, the intermediate layer 130′, and the lower channel stack ST1 may be partially removed by using the upper insulating layer 121 as an etch mask. The etching process may be carried out such that the front surface 110F1 of the substrate 110 may be exposed. Each of the upper channel stack ST2, the intermediate layer 130′, and the lower channel stack ST1 may be divided into a plurality of portions with a recess space SP between the portions.

An upper channel stack ST2, an intermediate layer 130′, and a lower channel stack ST1 may be respectively spaced apart from another upper channel stack ST2, another intermediate layer 130′, and another lower channel stack ST1 in the second horizontal direction (the Y axis direction). Each of the upper channel stack ST2, the intermediate layer 130′, and the lower channel stack ST1 may have a bar shape extending in the first horizontal direction (the X axis direction). In other words, a direction in which the upper channel stack ST2, the intermediate layer 130′, and the lower channel stack ST1 extend may cross a direction in which the placeholder PH extends. The topmost surface of the placeholder PH may be exposed by a process of FIG. 5.

Referring to FIG. 6, an insulating wall 123 may be formed to conformally cover opposite side surfaces of the lower channel stack ST1, the intermediate layer 130′, and the upper channel stack ST2 in the resultant structure of FIG. 5. A first mask layer M1 may be formed to cover the top surfaces of the upper insulating layer 121 and the insulating wall 123. The substrate 110 and the placeholder PH, which may be exposed by the recess space SP, may be etched by using the first mask layer M1 as an etch mask.

The insulating wall 123 may include a left insulating wall 123a and a right insulating wall 123b, which may be symmetrical with respect to each other and have the same thickness respectively on the opposite side surfaces of the lower channel stack ST1, the intermediate layer 130′, and the upper channel stack ST2. The top surface of the insulating wall 123 may be at the same vertical level as the top surface of the upper insulating layer 121. In other words, the left insulating wall 123a and the right insulating wall 123b may have substantially the same material and have the same thickness in the second horizontal direction (the Y axis direction) and height in the vertical direction (the Z axis direction).

Sidewalls of the placeholder PH may be exposed in the recess space SP by the etching process. The sidewalls of the placeholder PH may extend in the vertical direction (the Z axis direction) along the first placeholder PH1 and the second placeholder PH2 to the substrate 110. The etch of the placeholder PH may use the first mask layer M1 and may expose the substrate 110. The placeholder PH having a bar shape extending in the second horizontal direction (the Y axis direction) may be divided by the etch of the placeholder PH into a plurality of placeholders PH in a pattern of islands.

The substrate 110 may be exposed in the recess space SP by the etching of the second placeholder PH2. The height of an exposed top surface 110F2 of the substrate 110 (see FIG. 6) may be lower than the height of the front surface 110F1 of the substrate 110 (see FIG. 5) by the height of the placeholder PH in the vertical direction (the Z axis direction). Accordingly, a second thickness h2 of the substrate 110 in the vertical direction (the Z axis direction) in FIG. 6 may be less than a first thickness h1 of the substrate 110 in the vertical direction (the Z axis direction) in FIG. 5.

Referring to FIG. 7, the first mask M1 may be removed, and an inner spacer SPC may be formed on a sidewall of the first placeholder PH1 disposed below the insulating wall 123.

In embodiments, the inner spacer SPC may be formed below both the left insulating wall 123a and the right insulating wall 123b. The inner spacer SPC may be formed on an upper surface of the second placeholder PH2 and on a sidewall of the first placeholder PH1. The inner spacer SPC may not be formed on a sidewall of the second placeholder PH2. That is, the inner spacer SPC may be formed on an upper sidewall portion of the placeholder PH exposed in the recess space SP, and may expose the second placeholder PH2 to the recess space SP.

The inner spacer SPC may be formed of an insulating material. The inner spacer SPC may be formed an insulating material, such as silicon oxide, silicon nitride, or silicon oxynitride.

The inner spacer SPC may be formed to have a sidewall inset from a sidewall of the second placeholder PH2. For example, a sidewall of the inner spacer SPC, which may be a surface of the inner spacer SPC exposed in the recess space SP, may have a concave shape. A degree of the concave shape may depend on a difference in materials between the first placeholder PH1 and the second placeholder PH2. The thickness of the inner spacer SPC in the vertical direction (the Z axis direction) may correspond to a distance from the top surface of the second placeholder PH2 to the bottom surface of the insulating wall 123. The width of the inner spacer SPC in the second horizontal direction (the Y axis direction) may vary with a process of forming the inner spacer SPC. In an example, the inner spacer SPC may be formed to have an inset depth extending inward from the surface of the insulating wall 123 and the second placeholder PH2. A degree of the inset depth may control a shape of a lower portion of the lower gate line GL1.

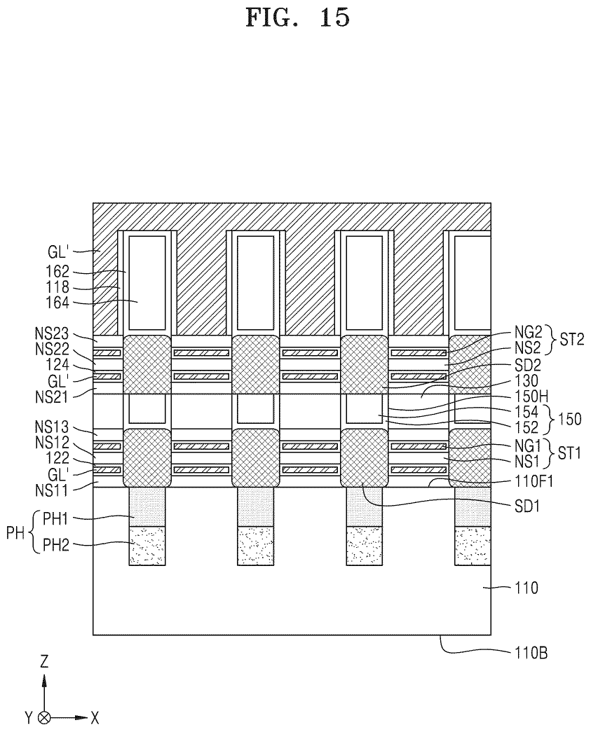

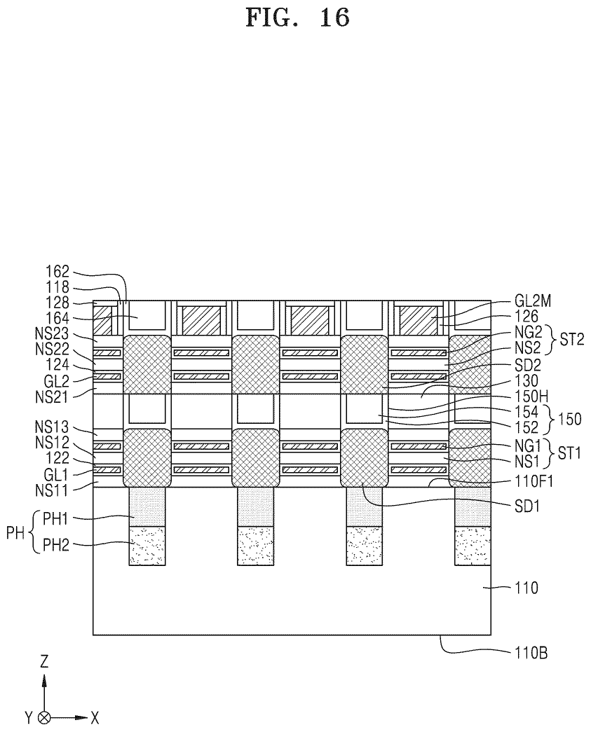

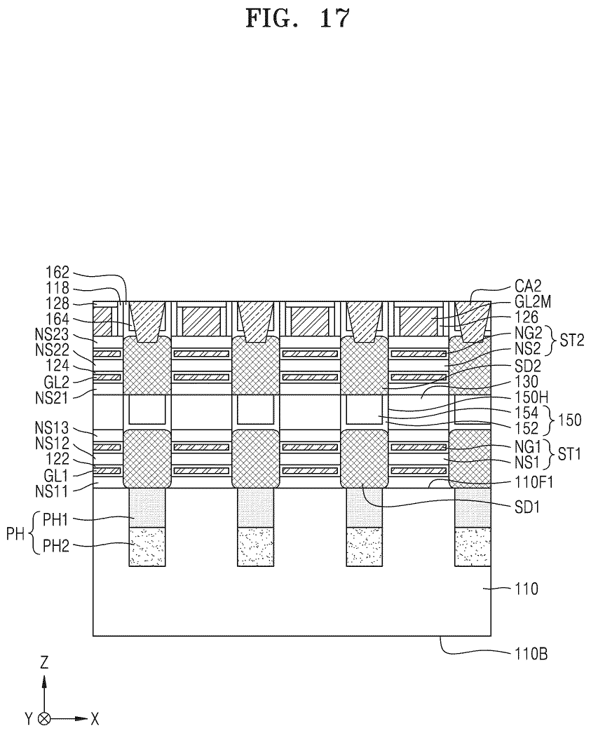

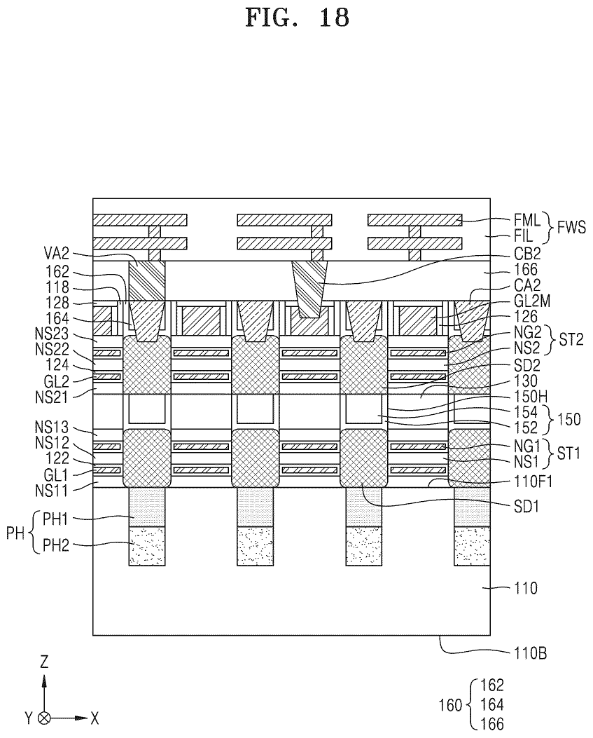

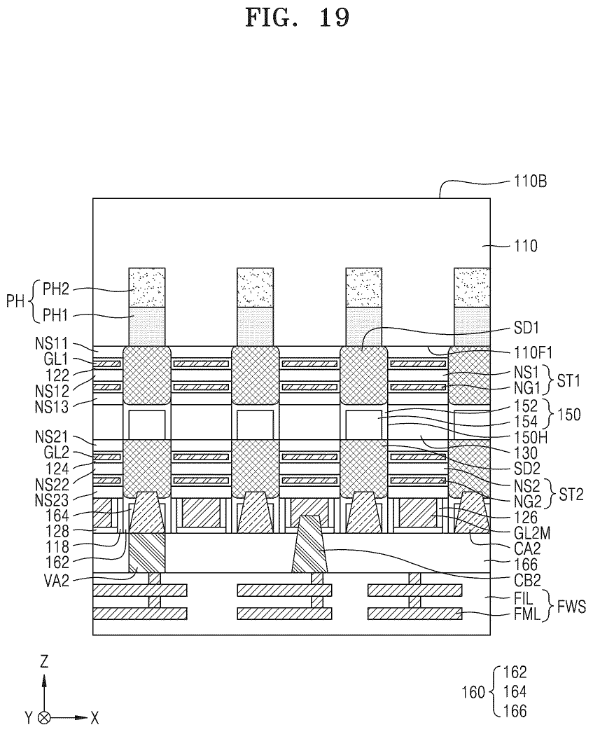

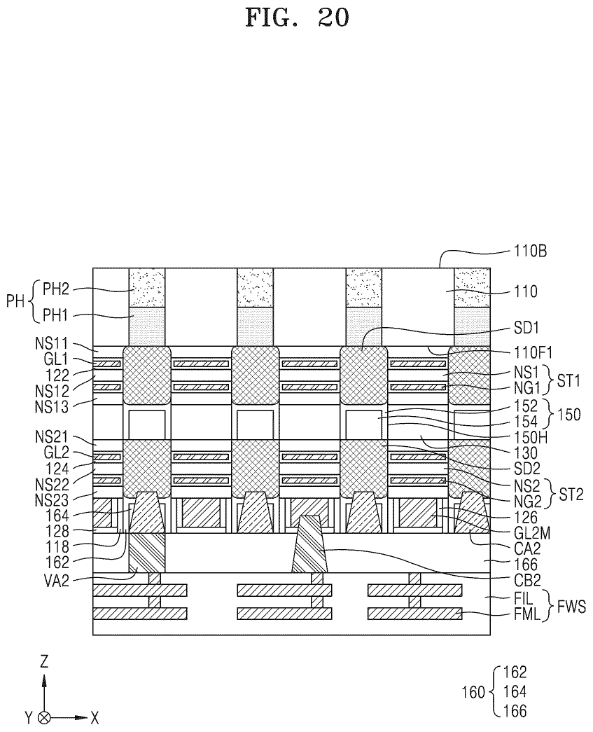

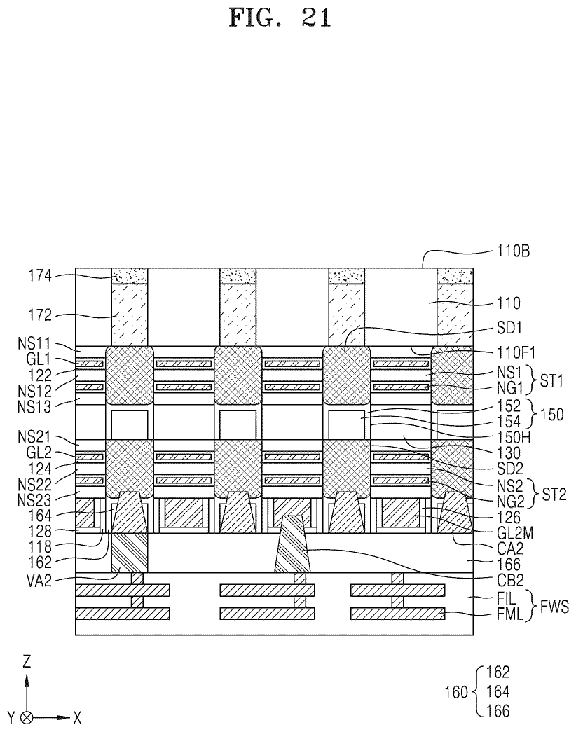

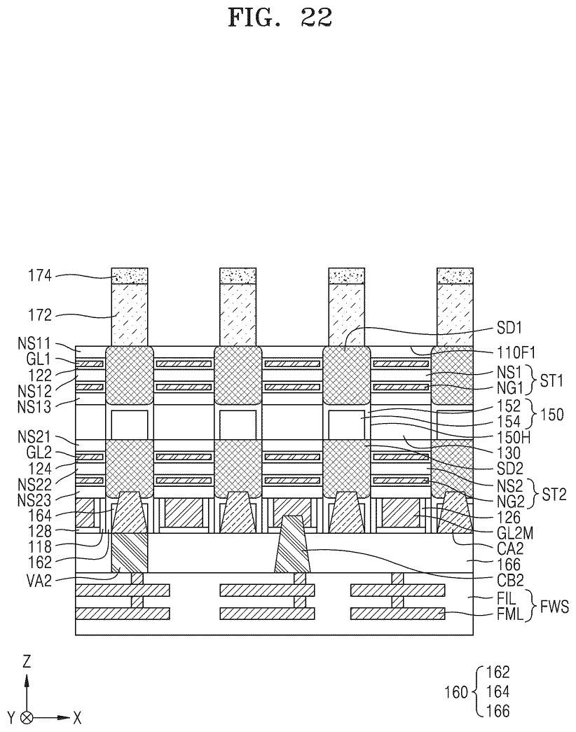

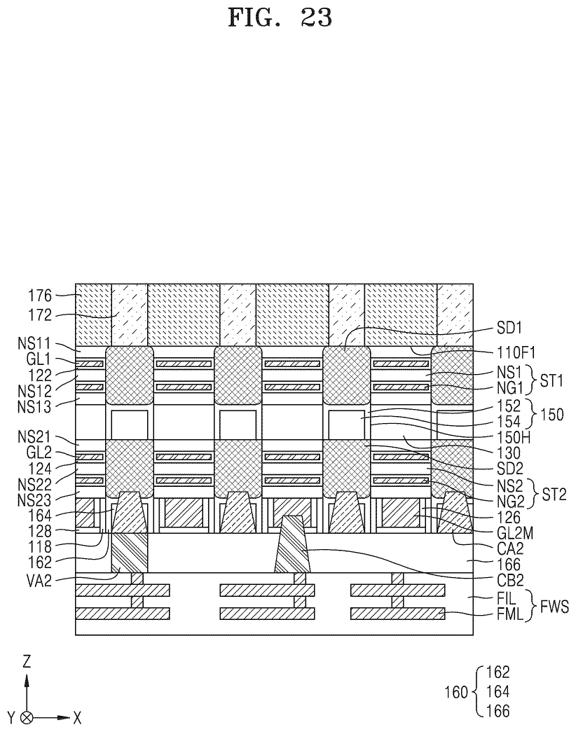

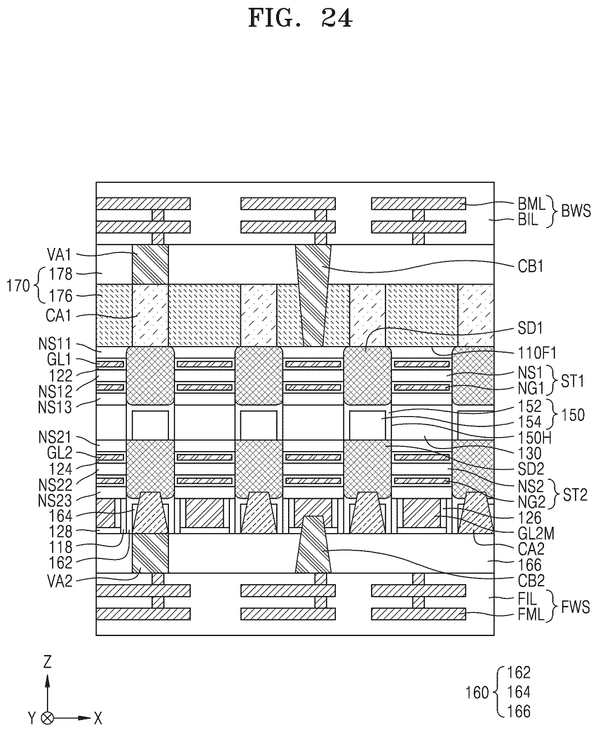

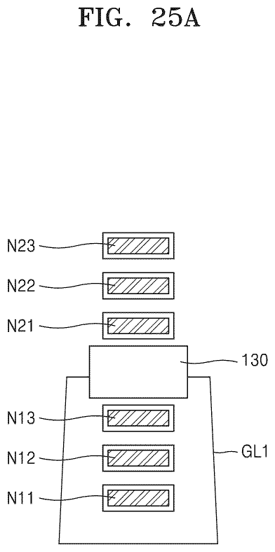

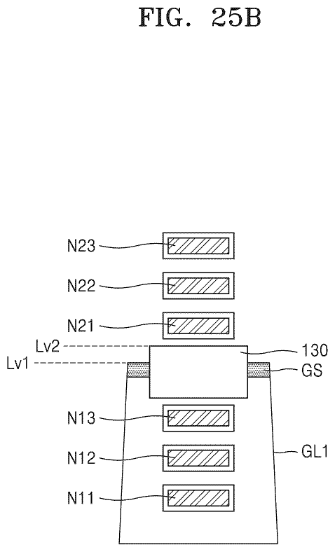

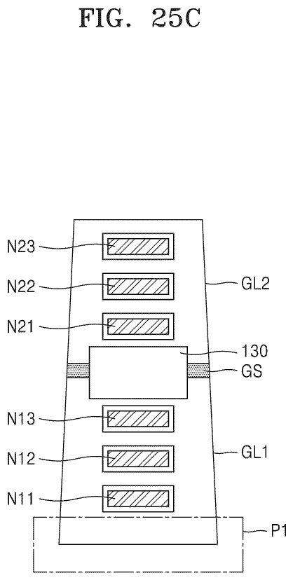

The structure of a completed device may be changed due to a process difference. Details of an example process different are described herein with reference to FIG. 25A, FIG. 25B, and FIG. 25C.

Referring to FIG. 8, a portion of the recess space SP may be filled with an insulating layer 125. The insulating wall 123 (see FIG. 7) and the upper insulating layer 121 (see FIG. 7) may be removed. An oxide film 127 may be formed to conformally cover the top surface of the insulating layer 125 and the exposed surfaces of the lower channel stack ST1, the intermediate layer 130′, and the upper channel stack ST2, and on a top surface of the upper channel stack ST2. The oxide film 127 may cover a top of the inner spacer SPC exposed by removing the insulating wall 123. The oxide film 127 may cover a portion of the first placeholder PH1 above the inner spacer SPC and exposed by removing the insulating wall 123.

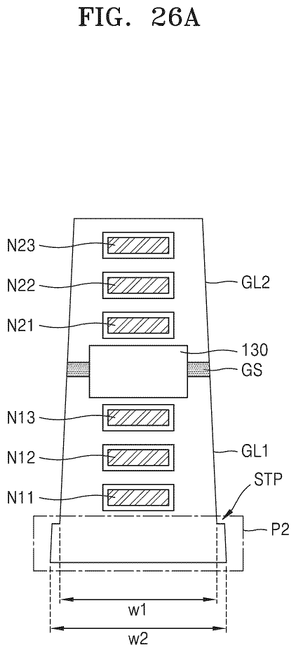

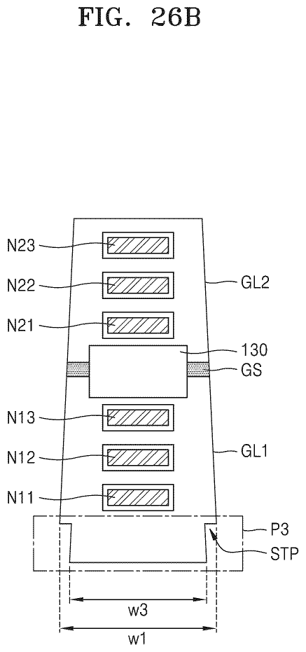

A thickness of the oxide film 127 may be less than a thickness of the insulating wall 123. As shown in FIG. 8, the inner spacer SPC may be inset to have a width less than, equal to, or greater than a width of the recess space SP between opposing portions of the insulating wall 123. In FIG. 8, the inner spacer SPC has an inset that is relatively shallow, for example, relative to the insulating wall 123, and may correspond to the lower gate line GL1 of FIG. 26B. In another example, the inner spacer SPC may have an inset that is relatively deep, for example, relative to the insulating wall 123, and may correspond to the lower gate line GL1 of FIG. 26A.

The insulating layer 125 may fill the inner spacer SPC up to the vertical level of the top surface of the inner spacer SPC. In other words, the inner spacer SPC may not be exposed by the insulating layer 125 and the oxide film 127.

In embodiments, the oxide film 127 may include SiO₂. For example, the oxide film 127 may be an insulating film including SiO₂, but the inventive concept is not limited thereto.

Referring to FIG. 9, a plurality of dummy gate structures DGS may be formed on the upper channel stack ST2.

Each of the dummy gate structures DGS may extend lengthwise in the second horizontal direction (the Y axis direction). Each of the dummy gate structures DGS may have a structure in which an oxide film D122, a dummy gate layer D124, and a capping layer D126 are sequentially stacked. In embodiments, the dummy gate layer D124 may include polysilicon and the capping layer D126 may include a silicon nitride film. The oxide film D122 may correspond to the oxide film 127 in FIG. 7.

Referring to FIG. 10, a plurality of insulating spacers 118 may be formed to cover sidewalls of the dummy gate structures DGS. Portions of the upper channel stack ST2 and the intermediate layer 130′ may be removed by using the dummy gate structures DGS and the insulating spacers 118 as an etch mask. The etching of the upper channel stack ST2 and the intermediate layer 130′ may form a plurality of intermediate recesses RA. By a process described herein, the upper channel stack ST2 may be divided into a plurality of upper nanosheets NS2 spaced apart from each other in the first horizontal direction (the X axis direction) and a plurality of upper sacrificial layers NG2 spaced apart from each other in the first horizontal direction (the X axis direction).

To form the intermediate recesses RA, dry etching, wet etching, or a combination thereof may be used. In embodiments, to form the intermediate recesses RA, an HCl gas, a CL₂ gas, and/or SF₃ gas, or gases having similar etch characteristics to these gases may be used, but the inventive concept is not limited thereto.

Referring to FIG. 10, a preliminary insulating liner 152L may be formed to conformally cover the exposed surfaces of the intermediate recesses RA. The preliminary insulating liner 152L may cover sidewalls of the insulating spacers 118, the upper channel stack ST2, and the intermediate layer 130′. The preliminary insulating liner 152L may be anisotropically etched to expose a bottom of each of the intermediate recesses RA. For example, the etch of the preliminary insulating liner 152L may expose an upper surface of the lower channel stack ST1. Portions of the lower channel stack ST1 exposed by the intermediate recesses RA may be removed by using the dummy gate structures DGS (see FIG. 9), the insulating spacers 118, and the preliminary insulating liner 152L as an etch mask. The etch of the lower channel stack ST1 may expose the placeholder PH and divide the lower channel stack ST1 into a plurality of lower nanosheets NS1 spaced apart from each other in the first horizontal direction (the X axis direction) and a plurality of lower sacrificial layers NG1 spaced apart from each other in the first horizontal direction (the X axis direction). In a process described herein, a lower recess may be formed between the lower channel stacks ST1, which expose the placeholder PH. The lower recesses may extend each of the intermediate recesses RA. A plurality of lower source/drain regions SD1 may be formed to respectively fill the lower recesses.

The preliminary insulating liner 152L may include silicon nitride (SiN), silicon oxide (SiO), SiCN, SiBN, SION, SiOCN, SiBCN, or SiOC, or a combination thereof. In embodiments, the preliminary insulating liner 152L may include a material that is different from that of the insulating spacers 118. In some embodiments, the preliminary insulating liner 152L may include the same material as the insulating spacers 118.

To form the lower source/drain regions SD1, a selective epitaxial growth process may be carried out. In an initial stage of the selective epitaxial growth process, a semiconductor film may be locally and epitaxially grown from exposed surfaces of the lower nanosheets NS1 in the lower recesses and from surfaces of the substrate 110. As the selective epitaxial growth process progresses, the semiconductor film may gradually grow, and the lower source/drain regions SD1 may be obtained as shown in FIG. 10. The lower source/drain regions SD1 may have a height that covers sidewalls of the lower channel stack ST1.

In embodiments, when the lower source/drain regions SD1 include an Si layer doped with an n-type dopant, an Si source may be used to form the lower source/drain regions SD1 by carrying out the selective epitaxial growth process. Silane (SiH₄), disilane (Si₂H₆), trisilane (Si₃H₈), or dichlorosilane (SiH₂Cl₂) may be used as the Si source, but the inventive concept is not limited thereto. The n-type dopant may be selected from among phosphorus (P), arsenic (As), or antimony (Sb), but the inventive concept is not limited thereto.

Referring to FIG. 11, a plurality insulating line structures 150 may be formed. The plurality insulating line structures 150 may include an insulating liner 152 and an insulating buried layer 154. The plurality insulating line structures 150 may cover the exposed surfaces of the lower source/drain regions SD1 in the resultant structure of FIG. 10. The vertical level of the topmost surface of the insulating line structures 150 may be about equal to or lower than the vertical level of the bottommost surface of the upper nanosheets NS2. For example, the vertical level of the topmost surface of the insulating line structures 150 may be lower than the vertical level of the bottommost surface of the upper nanosheets NS2 the bottom surface of the first upper nanosheet NS21. In embodiments, the insulating buried layer 154 may include silicon nitride (SiN), silicon oxide (SiO), SiCN, SiBN, SION, SIOCN, SiBCN, or SiOC, or a combination thereof.

Subsequently, the preliminary insulating liner 152L may be partially etched back. The etching of the preliminary insulating liner 152L may expose the sidewalls of the insulating spacers 118 and the top surfaces of a plurality of insulating buried layers 154, the sidewalls of the upper nanosheets NS2, and the sidewalls of upper sacrificial layers NG2.

After the recesses are formed, a portion of the preliminary insulating liner 152L may remain and may for a portion of the insulating liner 152. A bottom portion of the insulating liner 152 may be formed, which may connect sidewall portions of the insulating liner 152 formed from the preliminary insulating liner 152L. The bottom portion of the insulating liner 152 may include a material that is different from that of the preliminary insulating liner 152L. In some embodiments, the bottom portion of the insulating liner 152 may include the same material as the preliminary insulating liner 152L. In some embodiments, the preliminary insulating liner 152L remaining after the formation of the lower source/drain regions SD1 may from the insulating liner 152. For example, the bottom portion of the insulating liner 152 formed on an upper surface of the lower source/drain regions SD1 and illustrated in FIG. 10 may be omitted, and the preliminary insulating liner 152L formed on sidewalls of the intermediate recesses RA may expose at least a portion of the upper surface of the lower source/drain regions SD1.

The insulating liner 152 and the insulating buried layer 154 may define a bottom of each recess. A plurality of upper source/drain regions SD2 may be formed on the insulating line structures 150 in the intermediate recesses RA.

To form the upper source/drain regions SD2, a selective epitaxial growth process may be carried out. In an initial stage of the selective epitaxial growth process, a semiconductor film may be locally and epitaxially grown from the exposed surfaces of the upper nanosheets NS2 in the recesses. As the selective epitaxial growth process progresses, the semiconductor film may gradually grow, and the upper source/drain regions SD2 may be obtained as shown in FIG. 10. The upper source/drain regions SD2 may have a height that covers sidewalls of the upper channel stack ST2.

In embodiments, when the upper source/drain regions SD2 include an SiGe layer doped with a p-type dopant, an Si source and a Ge source may be used to form the SiGe layer doped with the p-type dopant. Silane (SiH₄), disilane (Si₂H₆), trisilane (Si₃H₈), or dichlorosilane (SiH₂Cl₂) may be used as the Si source. Germane (GeH₄), digermane (Ge₂H₆), trigermane (Ge₃H₈), tetragermane (Ge₄H₁₀), or dichlorogermane (Ge₂H₂Cl₂) may be used as the Ge source. The p-type dopant may be selected from boron (B) or gallium (Ga).

Referring to FIG. 12, an etch stop layer 162 may be formed to cover the resultant structure of FIG. 12, in which the upper source/drain regions SD2 have been formed. After a protective layer 164 is formed on the etch stop layer 162, the top surface of the capping layer D126 may be exposed by planarizing the etch stop layer 162 and the protective layer 164. Thereafter, the top surface of the dummy gate layer D124 may be exposed by removing the capping layer D126, and the etch stop layer 162, and the protective layer 164 may be partially etched such that the top surface of the protective layer 164 is substantially at the same level as the top surface of the dummy gate layer D124.

Referring to FIG. 13, a gate space G may be formed by removing the dummy gate layer D124 and the oxide film D122 below the dummy gate layer D124 in the resultant structure of FIG. 12. The top surfaces of the upper nanosheets NS2 may be exposed by the gate space G.

Referring to FIG. 14, the gate space G may be expanded to above the substrate 110 by removing the lower sacrificial layers NG1 and the upper sacrificial layers NG2, which have remained above the substrate 110, from the resultant structure of FIG. 13 through the gate space G. In this process, the intermediate layer 130′ may also be removed.

In embodiments, the lower sacrificial layers NG1 and the upper sacrificial layers NG2 may be selectively removed by using the difference in etch selectivity between the lower and upper nanosheets NS1 and NS2 and the lower and upper sacrificial layers NG1 and NG2. To selectively remove the lower and upper sacrificial layers NG1 and NG2, a liquid or gaseous etchant may be used. In embodiments, a CH₃COOH-based etchant, e.g., an etchant including a mixture of CH₃COOH, HNO₃, and HF or a mixture of CH₃COOH, H₂O₂, and HF, may be used to selectively remove the lower and upper sacrificial layers NG1 and NG2, but the inventive concept is not limited thereto.

After the gate space G is expanded to the top surface 110F1 of the substrate 110, the lower source/drain regions SD1 and the upper source/drain regions SD2 may be exposed by the gate space GS.

Referring to FIG. 15, gate insulating layers (e.g., a lower gate insulating layer 122 and an upper gate insulating layer 124) may be formed to cover the exposed surfaces of the substrate 110, the lower nanosheets NS1, the upper nanosheets NS2, the lower source/drain regions SD1, and the upper source/drain regions SD2 through the gate space G in the resultant structure of FIG. 14. In embodiments, a lower gate insulating layer 122 may cover the exposed surfaces of the lower nanosheets NS1 and the lower source/drain regions SD1, and an upper gate insulating layer 124 may cover the exposed surfaces of the upper nanosheets NS2 and the upper source/drain regions SD2. The upper gate insulating layer 124 and the lower gate insulating layer 122 may include substantially the same material and may be simultaneously formed. To form the lower gate insulating layer 122 and the upper gate insulating layer 124, an atomic layer deposition (ALD) process may be used. Before, after, or simultaneously with a process of forming the lower gate insulating layer 122 and the upper gate insulating layer 124, a space in which the intermediate layer 130′ (see FIG. 13) has been arranged may be filled with an insulating structure 130.

Thereafter, a gate forming conductive layer GL′ may be formed above the gate insulating layers (122 and 124) to fill the gate space G (see FIG. 14) and cover the top surface of the protective layer 164. The gate forming conductive layer GL′ may include metal, metal nitride, or metal carbide, or a combination thereof. To form the gate forming conductive layer GL′, an ALD process or a CVD process may be used.

A lower gate line GL1 and an upper gate line GL2 may be obtained by removing an upper portion of the gate forming conductive layer GL′, such that the top surface of the protective layer 164 may be exposed and an upper portion of the gate space G is opened again. A remaining portion of the gate forming conductive layer GL′ may be the lower gate line GL1. While the gate space G is opened, a gate isolation structure GS may be formed on the lower gate line GL1. In embodiments, the gate isolation structure GS may include an insulating material. A vapor-deposition may be performed to form the gate forming conductive layer forming the upper gate line GL2. An example process may be described with reference to FIG. 25A, FIG. 25B, and FIG. 25C.

FIG. 25A, FIG. 25B, and FIG. 25C are schematic cross-sectional views of the central portion of the upper channel stack ST2 and the lower channel stack ST1, taken along a Y-Z plane, in sequential stages in a process of forming the lower gate line GL1 and the upper gate line GL2 in FIG. 15 and FIG. 16.

Referring to FIG. 25A, an upper portion of the gate forming conductive layer GL′ may be removed. After the upper portion of the gate forming conductive layer GL′ is removed, the vertical level of the topmost surface of a remaining portion of the gate forming conductive layer GL′ may be higher than the vertical level of the bottommost surface of the insulating structure 130 and lower than the vertical level of the topmost surface of the insulating structure 130. The remaining part of the gate forming conductive layer GL′ may become the lower gate line GL1.

Referring to FIG. 25B, a gate isolation structure GS may be formed on the lower gate line GL1. In embodiments, the gate isolation structure GS may include an insulating material. In embodiments, the thickness of the gate isolation structure GS in the vertical direction (the Z axis direction) may greater than about 5 nm, but is not limited thereto. In embodiments, a vertical level Lv1 of the topmost surface of the gate isolation structure GS may be lower than a vertical level Lv2 of the topmost surface of the insulating structure 130.

Referring to FIG. 25C, a gate forming conductive layer may be deposited. The gate forming conductive layer may be vapor-deposited on the gate isolation structure GS. The gate forming conductive layer may form the upper gate line GL2.

Each of the gate isolation structure GS and the insulating structure 130 may increase a structural stability of a vertically stacked FET structure. For example, the gate isolation structure GS and the insulating structure 130 may inhibit or prevent short-channel effects with adjacent vertically stacked FET structures by providing an improved structure supporting the upper gate line GL2.

Referring to FIG. 16, a spacer 126 may be formed on each of sidewalls of the main gate portion GL2M. A gate capping layer 128 may be formed on the upper gate line GL2. The gate capping layer 128 may overlap the spacer 126. The gate capping layer 128 may fill the gate space G (see FIG. 14).

Referring to FIG. 17, a mask pattern (not shown) may be formed on the gate capping layer 128. Upper contact holes (not shown) may be formed by removing a portion of the protective layer 164 by using the mask pattern. The upper contact holes may be formed to a depth such that the upper source/drain regions SD2 may be exposed. The upper contact holes may extend into an upper portion of the upper source/drain regions SD2. An upper contact CA2 may be formed in the upper contact hole by using a conductive material.

Referring to FIG. 18, an upper insulating layer 166 may be formed on the upper contact CA2 and the protective layer 164. An upper via hole (not shown) and a gate contact hole (not shown) may be formed by partially removing the upper insulating layer 166. Thereafter, an upper via VA2 may be formed by filling the upper via hole with a conductive material and an upper gate contact CB2 may be formed by filling the gate contact hole with a conductive material. Thereafter, a front wiring structure FWS electrically connected to the upper via VA2 and the upper gate contact CB2 may be formed.

Referring to FIG. 19 and FIG. 20, the substrate 110 may be turned over such that the back surface 110B of the substrate 110 faces upwards, and the substrate 110 may be thinned such that the placeholder PH may be exposed from the back surface 110B of the substrate 110.

Referring to FIG. 21, the placeholder PH (see FIG. 19) may be removed, and an oxide pattern 172 may be formed in a space from which the placeholder PH has been removed. An upper portion of the oxide pattern 172 may be recessed, and a nitride pattern 174 may be formed on the recessed top surface of the oxide pattern 172. In embodiments, the nitride pattern 174 may include SiN.

Referring to FIG. 22 and FIG. 23, the substrate 110 may be removed. The oxide pattern 172 and the nitride pattern 174 may remain on the lower source/drain regions SD1SD1. A space between adjacent oxide patterns 172 may be filled with a first base insulating layer 176. In embodiments, the process of removing the substrate 110 may include a wet etching process. After the first base insulating layer 176 is formed, the nitride pattern 174 on the oxide pattern 172 may be polished such that the top surface of the oxide pattern 172 may be exposed. In embodiments, the first base insulating layer 176 may include SiN. The top surface of the oxide pattern 172 may be at the same vertical level as the top surface of the first base insulating layer 176.

Referring to FIG. 24, the oxide pattern 172 may be removed, and a lower contact CA1 may be formed in a space from which the oxide pattern 172 has been removed. A second base insulating layer 178 may be formed on the lower contact CA1 and the first base insulating layer 176. A lower via hole (not shown) and a gate contact hole (not shown) may be formed by removing portions the second base insulating layer 178. A lower via VA1 may be formed by filling the lower via hole with a conductive material and a lower gate contact CB1 may be formed by filling the gate contact hole with a conductive material. The lower via VA1 and the lower gate contact CB1 may be formed of a same conductive material or a different conductive material. A back wiring structure BWS electrically connected to the lower via VA1 and the lower gate contact CB1 may be formed.

FIG. 26A and FIG. 26B are schematic cross-sectional views illustrating a part of an integrated circuit device, according to embodiments.

Referring to FIG. 26A and FIG. 26B together with FIG. 25C, lower portions (P1 in FIG. 25C, P2 in FIG. 26A, and P3 in FIG. 26B) of the lower gate line GL1 may have different shapes from each other. These structural differences may be described with reference to FIG. 7 and FIG. 8.

FIG. 25C, FIG. 26A, and FIG. 26B are cross-sectional view schematically showing a Y-Z plane taken along line B-B′ in FIG. 8. In a process of forming the inner spacer SPC, when an inset of the inner spacer SPC is formed relatively shallow, the lower gate line GL1 may have the lower portion P3 (in FIG. 26B) that has a width less w3 than a width w1 of the upper portion of the lower gate line GL1. For example, the shape of the lower gate line GL1 may include a step STP between the lower portion P3 and the upper portion of the lower gate line GL1. In the case that an inset of the inner spacer SPC is formed relatively deep, the lower portion of the lower gate line GL1 may have a width w2 greater than the width w1 the upper portion of the lower gate line GL1 (see P2 in FIG. 26A) such that a wider shape may be formed below the upper portion of the lower gate line GL1. Similar to FIG. 26B, the shape of the lower gate line GL1 in FIG. 26A may include a step STP between the lower portion P2 and the upper portion of the lower gate line GL1. As described herein, the shape of the inner spacer SPC may define a space where the lower gale line GL1 may be formed, and may control the shape of the lower portion of the lower gate line GL1. When an inset of the inner spacer SPC is formed in a medium position, the lower and upper portions of the lower gate line GL1 may be integrally formed and may have aligned widths (see P1 in FIG. 25C) such that the cross-section of the lower gate line GL1 may have linear sidewalls. For example, the lower gate line GL1 may have a form of a large trapezoidal shape. The shape of the lower gate line GL1 may be varied according to a process of forming the inner spacer SPC, and the width and shape of the lower portion of the lower gate line GL1 are not limited to embodiments described herein.

A shape of the lower portion of the lower gate line GL1 may provide improved structural stability. For example, a shape of the lower portion of the lower gate line GL1 may improve a structural connection with the back insulating structure 170.

While the inventive concept has been particularly shown and described with reference to embodiments thereof, it will be understood that various changes in form and details may be made therein without departing from the spirit and scope of the following claims.

What is claimed is:

1. A method of manufacturing an integrated circuit device, the method comprising:
forming a placeholder in an upper portion of a substrate;
forming a lower channel stack extending in a first horizontal direction, by alternately vapor-depositing a plurality of lower nanosheets and a plurality of lower sacrificial layers on the substrate, and forming an upper channel stack extending in the first horizontal direction, by alternately vapor-depositing a plurality of upper nanosheets and a plurality of upper sacrificial layers above the lower channel stack;
forming a recess space by removing portions of the upper channel stack, the lower channel stack, and the placeholder and forming an inner spacer in an upper portion of the placeholder;
forming, sequentially, an insulating layer, a lower source/drain region, and an upper source/drain region in the recess space;
removing the plurality of lower sacrificial layers and the plurality of upper sacrificial layers, forming a lower gate insulating layer covering exposed surfaces of the lower source/drain region and the plurality of lower nanosheets, and forming an upper gate insulating layer covering exposed surfaces of the upper source/drain region and the plurality of upper nanosheets;
forming a lower gate line on the lower gate insulating layer and forming an upper gate line on the upper gate insulating layer;
forming an upper contact, a gate contact and an upper via, on the upper channel stack and the upper source/drain region;
exposing the placeholder by polishing the substrate;
removing the placeholder from the substrate and forming a lower contact in a space from which the placeholder has been removed;
removing the substrate and filling a space from which the substrate has been removed with a first base insulating layer;
forming a second based insulating layer on the first base insulating layer and the lower contact; and
forming a lower via penetrating the first base insulating layer and contacting the lower contact, and forming a lower gate contact penetrating the first base insulating layer and contacting the lower channel stack.

2. The method of claim 1, wherein forming of the placeholder comprises:
forming a recess in the substrate;
forming a second placeholder in the recess; and
forming a first placeholder on the second placeholder in the recess.

3. The method of claim 2, wherein
the first and second placeholders include silicon-germanium, and
a concentration of germanium in the first placeholder is different from a concentration of germanium in the second placeholder.

4. The method of claim 3, wherein
a difference between the concentration of germanium in the first placeholder and the concentration of germanium in the second placeholder is about 10% to about 15%.

5. The method of claim 2, wherein
the inner spacer is formed on the second placeholder and in a portion of the first placeholder.

6. The method of claim 2, further comprising etching a portion of the first placeholder forming an indent in the first placeholder.

7. The method of claim 1, wherein the forming of the lower gate line and the upper gate line comprises:
forming a gate isolation structure on the lower gate line; and
forming the upper gate line on the gate isolation structure.

8. The method of claim 7, further comprising:
forming an insulating structure on the lower gate line,
wherein the gate isolation structure is formed on a portion of the lower gate line, and
a top surface of the gate isolation structure is at a lower vertical level than a top surface of the insulating structure between the plurality of lower nanosheets and the plurality of upper nanosheets.

9. The method of claim 8, wherein
a width of the gate isolation structure in a second horizontal direction that crosses the first horizontal direction is greater than a width of the insulating structure on the lower gate line.

10. The method of claim 7, wherein the gate isolation structure physically separates the lower gate line from the upper gate line.

11. The method of claim 7, wherein a height of the gate isolation structure in a vertical direction is at least 5 nm.

12. The method of claim 1, wherein a width of the lower gate line includes a step.

13. A method of manufacturing an integrated circuit device, the method comprising:
forming a placeholder in an upper portion of a substrate, the placeholder being spaced apart from an adjacent placeholder in a first horizontal direction and extending in a second horizontal direction;
forming, sequentially, a lower channel stack, an intermediate layer, and an upper channel stack, on the substrate;
forming a recess space by removing portions of the upper channel stack, the intermediate layer, the lower channel stack, and the placeholder;
removing an upper portion of the placeholder and forming an inner spacer in the upper portion of the placeholder;
forming, sequentially, an insulating layer, a lower source/drain region and an upper source/drain region in the recess space;
removing a sacrificial layer included in the lower channel stack and the upper channel stack and the intermediate layer, and forming a lower gate insulating layer on an exposed surface of the lower channel stack and an upper gate insulating layer on an exposed surface of the upper channel stack;
forming a lower gate line on the lower gate insulating layer and an upper gate line on the upper gate insulating layer;
forming an upper contact, a gate contact, and an upper via, on the upper channel stack and the upper source/drain region;
exposing the placeholder by polishing the substrate;
removing the placeholder from the substrate and forming a lower contact in a space from which the placeholder has been removed;
removing the substrate and filling a space from which the substrate has been removed with a first base insulating layer;
forming a second based insulating layer on the first base insulating layer and the lower contact;
forming a lower contact via penetrating the first base insulating layer and contacting the lower contact and forming a lower gate contact penetrating the first base insulating layer and contacting the lower channel stack; and
forming a gate isolation structure between the lower gate line and the upper gate line after the forming of the lower gate line and before the forming of the upper gate line.

14. The method of claim 13, wherein forming the placeholder comprises:
forming a recess extending in the second horizontal direction in the substrate;
forming a second placeholder in the recess; and
forming a first placeholder on the second placeholder in the recess.

15. The method of claim 14, wherein
the first placeholder and the second placeholder include silicon-germanium, and a concentration of germanium in the first placeholder is different from a concentration of germanium in the second placeholder.

16. The method of claim 13, wherein
a width of the lower gate line includes a step.

17. The method of claim 13, further comprising
removing the intermediate layer and forming an insulating structure in a space from which the intermediate layer has been removed.

18. The method of claim 17, wherein
the gate isolation structure is formed on a portion of the lower gate line, and
a top surface of the gate isolation structure is at a lower vertical level than a top surface of the insulating structure.

19. A method of manufacturing an integrated circuit device, the method comprising:
providing a substrate including a placeholder disposed in an upper portion thereof;
forming, sequentially, a lower channel stack, an intermediate layer, and an upper channel stack, on the substrate;
forming a recess space by removing portions of the upper channel stack, the intermediate layer, the lower channel stack, and the placeholder to expose the substrate;
etching an upper portion of the placeholder and forming an inner spacer on an upper portion of the placeholder;
forming, sequentially, an insulating layer, a lower source/drain region of a first conductivity type and an upper source/drain region of a second conductivity type in the recess space;
removing a sacrificial layer included in the lower channel stack and the upper channel stack and the intermediate layer;
forming a lower gate insulating layer on an exposed surface of the lower channel stack;
forming an upper gate insulating layer on an exposed surface of the upper channel stack;
forming an insulating structure in a space from which the intermediate layer has been removed, and forming a gate forming conductive layer;
forming a lower gate line by removing an upper portion of the gate forming conductive layer;
forming a gate isolation structure on the lower gate line, wherein a top surface of the gate isolation structure is at a lower vertical level than a top surface of the insulating structure;
forming an upper gate line on the gate isolation structure;
forming an upper contact, a gate contact and an upper via, on the upper channel stack and the upper source/drain region, and forming a front wiring structure on the upper contact, the gate contact, and the upper via;
exposing the placeholder by polishing the substrate;
removing the placeholder from the substrate and forming a lower contact in a space from which the placeholder has been removed;
removing the substrate and filling a space from which the substrate has been removed with a first base insulating layer; and
forming a lower contact via penetrating the first base insulating layer and contacting the lower contact and a lower gate contact penetrating the first base insulating layer and contacting the lower channel stack.

20. The method of claim 19, further comprising forming the placeholder in the substrate, wherein forming the placeholder comprises:
forming a recess extending in the substrate;
forming a second placeholder in the recess; and
forming a first placeholder on the second placeholder in the recess,
wherein the inner spacer is formed on a sidewall of the first placeholder and on an upper surface of the second placeholder.
